(19) United States
(12) Patent Application Publication
(10) Pub. No.: US 2006/0187698 A1
(43) Pub. Date: Aug. 24, 2006

(54) System and method for dynamic checking

(76) Inventors: Igor J. Schmidt, San Jose, CA (US); Alexander Gelf, Cupertino, CA (US)

Correspondence Address: CARR & FERRELL LLP, 2200 GENG ROAD, PALO ALTO, CA, 94303, US

(21) Appl. No.: 11/350,957

(22) Filed: Feb. 8, 2006

Related U.S. Application Data
(60) Provisional application No. 60/650,856, filed on Feb. 8, 2005.

(51) Int. Cl. G11C 17/00

(52) U.S. Cl. 365/96

(57) ABSTRACT

Systems and methods for utilizing dynamic checks is provided. A user provides user identification information via a POS terminal. The identification information is used to obtain account information such that a representation of the dynamic check may be generated based on the account information. The dynamic check is populated with the user's account information including name, routing, and bank account information. In some embodiments, the payment amount is automatically provided on the dynamic check. After review, the user provides his/her signature on the dynamic check. In exemplary embodiments, this signature is verified by comparing the signature with a stored template of the signature associated with the user's account. Once, the dynamic check is authenticated, the dynamic check may be processed for settlement.

### CROSS-REFERENCE TO RELATED APPLICATION

This application claims the priority of U.S. Provisional Patent Application Ser. No. 60/650,856 entitled “System for Creating and Processing Dynamic Electronic Checks,” filed Feb. 8, 2005, the subject matter of which is hereby incorporated by reference.

### BACKGROUND

1. Technical Field

Embodiments of the present invention relate generally to financial services, and more particularly to systems and methods for processing electronic payments.

2. Description of Related Art

Using checks to make payment is one of the most traditional payment methods in use. Typically, an individual using a paper check must fill in proper fields on the paper check including payee information, date, payment amount (both in numerical and written forms) and an optional note or memo. The individual must then sign the paper check in order to authorize the payment, and hands the paper check over to a clerk for local processing.

The use of the paper check at a point of service/sale is often slow and tedious. While the individual may be able to fill in some information prior to reaching the point of service/sale, the individual must wait until a final payment amount due is calculated before filling in those fields on the paper check, and signing the paper check.

Once the paper check is handed over to the clerk, the clerk typically needs to verify proper identification and locally process the check. That is the clerk will request the individual show some form of identification. Once identification is verified, the clerk may then scan the check and/or run the check through a cash register machine. For larger purchases, the clerk may be required to call a bank/financial institution associated with the paper check to verify sufficient balance to cover the amount of the paper check. All of these actions slow down the payment process at the point of service/sale.

Post service or sale, the payee deposits the paper check into his/her bank account so that the bank/financial institution can settle the funds (i.e., clear the check) based on a routing and account number on the paper check. In the simplest explanation, the payee's bank forwards the original (or a copy of the) paper check to the payer's bank, which then must manually verify the paper check. Once verified, the funds are forwarded to a payee's bank account.

The use and processing of paper checks is laborious, expensive, and prone to errors and fraud due to the paper-based nature of the check clearing process and manual verification of handwritten signatures. Therefore, there is a need for efficient systems and methods for utilizing dynamic, electronic checks.

### SUMMARY

Embodiments of the present invention provide systems and methods for utilizing dynamic checks. In exemplary embodiments, the user sets up an account which allows the user to make payments via dynamic (electronic) checks. When setting up the account, the user provides identification information which may be verified via, for example, comparison with driver license, government identification cards, credit cards, and their associated information. The user also provides bank checking account information. The various information may be entered via card readers, check scanners, keypads, and pressure sensitive pads, for example.

When the user desires to pay using a dynamic check, the user initiates the process by providing unique identification information via a POS terminal. The unique identification information may be, for example, a driver license number, telephone number, or account user name. This unique identification information is used to access and obtain account information for the user. The account information is then used to generate a representation of the dynamic check on the POS terminal.

The representation of the dynamic check is populated with the user's account information including name, routing, and bank account information. In some embodiments, the payment amount is automatically provided on the dynamic check. The user may review and edit any of the information automatically provided on the dynamic check.

After review, the user provides his/her signature on the dynamic check. In exemplary embodiments, this signature is verified by comparing the signature with a stored template of the signature associated with the user's account. Alternatively or in addition, one or more identification information sources, such as driver license and credit cards, may be references for authentication. Once, the dynamic check is authenticated, the dynamic check may be processed for settlement.

### BRIEF DESCRIPTION OF THE DRAWINGS

FIG. 1 illustrates an exemplary environment in which embodiments of the present invention may operate;

FIG. 2 is a block diagram of an exemplary POS terminal;

FIG. 3 is a block diagram of an exemplary data processing center;

FIG. 4 illustrates a digital check, according to one embodiment of the present invention;

FIG. 5 is a flowchart of an exemplary method for registering with the data processing center; and

FIG. 6 is a flowchart of an exemplary method for processing a dynamic check transaction.

### DETAILED DESCRIPTION OF EXEMPLARY EMBODIMENTS

Embodiments of the present invention provide systems and methods for creating and processing electronic checks. Since the electronic check is created on-the-fly in a dynamic manner, the electronic check may also be referred to as a dynamic check. By utilizing dynamic checks, consumers may pay by check even if they do not have their checkbooks with them. Additionally, identity theft may be reduced and check processing may occur more efficiently and with less error since paper-based processing is eliminated. A further advantage is that the use of dynamic checks is faster then the consumer manually writing a check, and may be as convenient as paying by credit card.

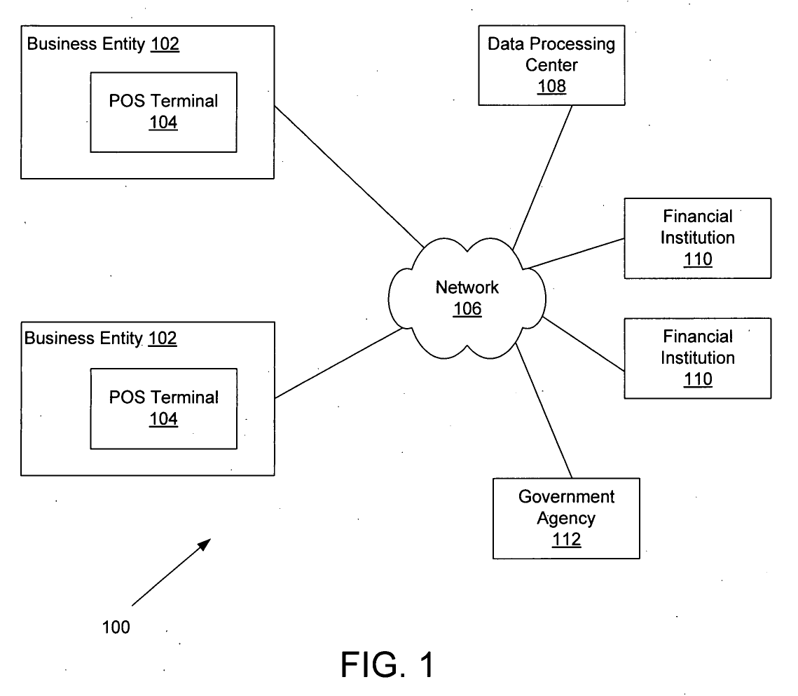

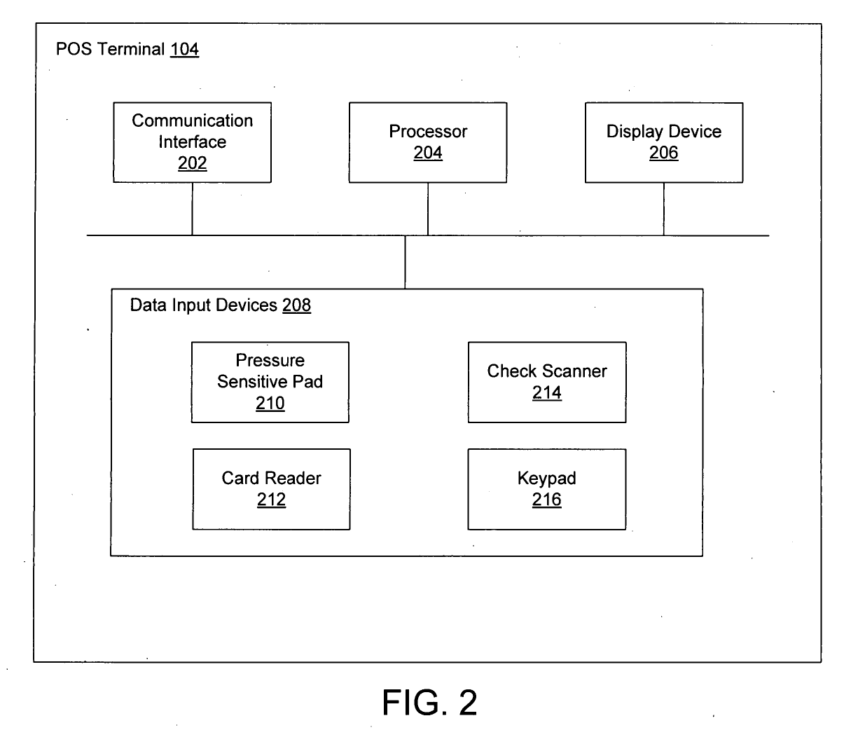

Referring to FIG. 1, an exemplary environment 100 in which embodiments of the present invention may be practiced is shown. The exemplary environment 100 comprises a plurality of business entities 102, each having at least one Point-of-Service (POS) terminal 104. The POS terminal 104 is a computing device configured to operate as an interface for an individual using a dynamic check. The POS terminal 104 will be discussed in more detail in connection with FIG. 2.

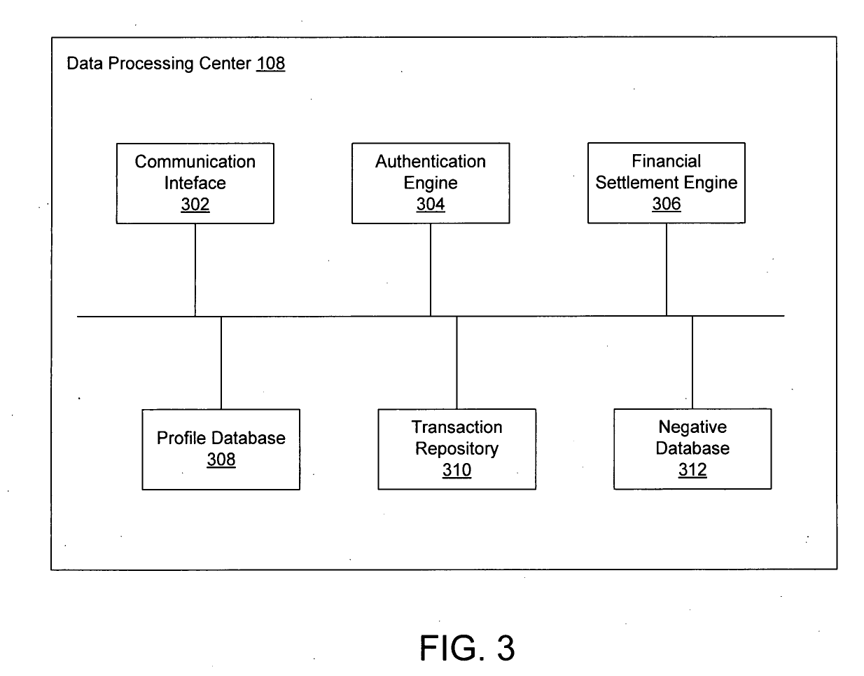

The plurality of business entities 102 are coupled via a network 106 to a data processing center 108. The data processing center 108 is configured to receive electronic check information and process the information in order to insure payment. The data processing center 108 will be discussed in more detail in connection with FIG. 3.

In some embodiments, the data processing center 108 is coupled via the network 106 to a plurality of banks or financial institutions 110 and/or at least one government agency 112. The financial institutions 110 may comprise, for example, banks and check clearing houses. Financial information, such as checking account information and check amounts, are communicated between the data processing center 108 and the financial institutions 110. The government agency 112 may comprise one or more Department of Motor Vehicles (DMV), or any other agency which can verify an individual's or entity's (e.g., business or legal entity) identification information.

While FIG. 1 shows an exemplary embodiment of the environment 100, alternative embodiments may comprise any number of business entities 102, data processing centers 108, financial institutions 110, and/or government agencies 112 coupled together. Further, the environment 100 may not include financial institutions 110 and government agencies 112. Instead, verifying information from the financial institution 110 and/or government agency 112 may be obtained off-line or through others means not related to the network 106.

It should be noted that while the business entities 102 are shown having at least one POS terminals 104 to enable dynamic check writing, other components may be provided for other payment options which work in parallel with dynamic checks. For example, the business entity 102 may also comprise card readers to allow for credit card transactions and cash registers.

Referring now to FIG. 2, a block diagram of the exemplary POS terminal 104 is shown. The POS terminal 104 and any associated POS infrastructure may be located at a place of business, such as a retailer, self-service kiosk, or any other location that accepts payment for a good or service. The associated POS infrastructure may comprise a cash register, bar code scanner, or any other computing device which provides information to the POS terminal 104.

In exemplary embodiments, the POS terminal 104 comprises a communication interface 202, a processor 204, a display device 206, and one or more data input devices 208. The communication interface 202 allows the POS terminal 104 to exchange data with other components in the environment 100 (FIG. 1) and/or within the business entity 102 (FIG. 1). For example, the communication interface 202 may receive a total payment amount from a coupled cash register, and forward payment request information to the data processing center 108 (FIG. 1).

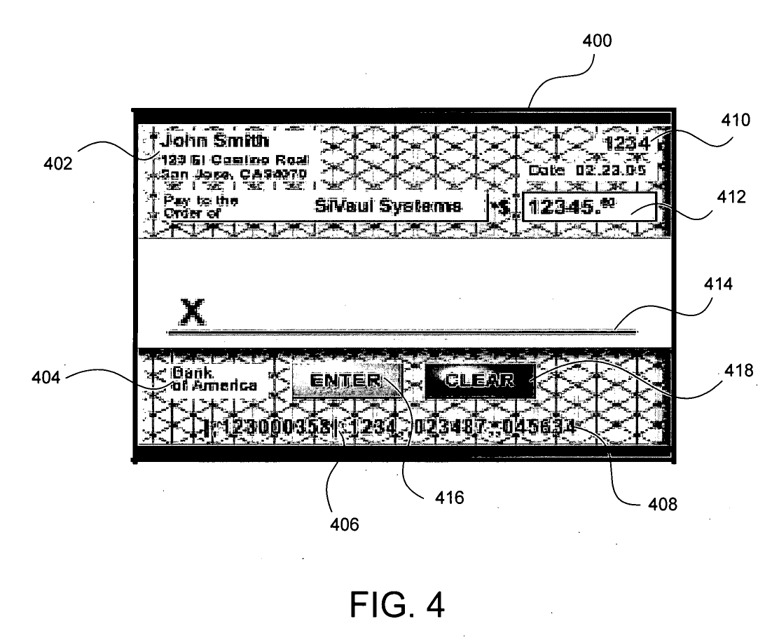

The display device 206 comprises a screen which shows an individual's information related to payment and a dynamic check. In some embodiments, the display device 206 may comprise a liquid crystal display (LCD) screen. In exemplary embodiments, the dynamic check, which resembles a paper check (e.g., shown in FIG. 4) may be displayed on the display device 206. The dynamic check will be discussed in more detail in connection with FIG. 4.

The data input devices 208 may comprise a pressure sensitive pad 210, a card reader 212, a check scanner 214, a keypad 216, and/or any combination of these and other data input devices 208. In exemplary embodiments, the pressure sensitive pad 210 may be integrated with the display device 206, thus providing the dynamic check which may be “written” upon via the pressure sensitive pad 210. It should be noted that the card reader 212 and check scanner 214 may be located outside of the POS terminal 104, and in some embodiments, be coupled to the POS terminal 104.

The card reader 212 is enabled to read information from cards such as credit cards or driver licenses. In exemplary embodiments, the card reader 212 comprises a mechanism which can “read” magnetic strips or barcode data from these cards.

The check scanner 214 is a device which reads information from a physical check. That is, the routing and account data normally found on a bottom portion of the physical check can be read by the check scanner 214.

As previously discussed, embodiments of the present invention allow for payment transactions that operate in parallel or in supplement to those of the dynamic checking functionalities of the POS terminal 104. For example, credit card and paper check transactions may take place at the business entity 102. The credit card transaction may be facilitated via the card reader 212 on the POS terminal 104, and the individual may, for example, present their signature for the credit card transaction through the pressure sensitive pad 210. The paper check may be scanned by the check scanner 214 to read and/or verify the banking information located at the bottom of the paper check.

The POS terminal 104 comprises any computing device enabled to process transactions which is coupled to input devices enabled for biometric capture, such as the pressure sensitive pad 210. Further, the POS terminal 104 may comprise a plurality of computing hardware wherein a single or plurality of POS terminals 104 are used in conjunction with other computing devices that facilitate payment transaction. The other computing devices may comprise host servers, electronic cash registers and their associate software, and other hardware, software, and/or equipment. The operation of the POS terminal 104 will be discussed in more detail in connection with FIG. 4-FIG. 6 below.

Referring now to FIG. 3, a block diagram of the exemplary data processing center 108 is shown. In one embodiment, the data processing center 108 comprises a communication interface 302, an authentication engine 304, a financial settlement engine 306, a profile database 308, a transaction repository 310, and a negative database 312. Alternative embodiments may comprise more, few, or functionally equivalent components. For example, one or more of the profile database 308, transaction repository 310, and negative database 312 may be located outside of the data processing center 108 but be coupled thereto. Alternatively, the databases 308 and 312 and repository 310 may be combined into few databases, or each database 308 and 312 and repository 310 may comprise a plurality of databases.

The communication interface 302 allows the data processing center 108 to exchange data with other components in the environment 100 (FIG. 1). Specifically, the communication interface 302 provides a gateway for information from the POS terminals 104 (FIG. 1) to be received and processed by the data processing center 108. Additionally, the communication interface 302 allows data exchange between the data processing center 108 and various financial institutions 110 (FIG. 1), government agencies 112 (FIG. 1), and/or databases (e.g., databases 308, 310, and/or 312 not located within the data processing center 108).

The exemplary authentication engine 304 is configured to verify an identity of the user of the dynamic check. In some embodiments, the authentication engine 304 will receive verification information (e.g., signature, driver license data, or credit card data) and compare the verification information to information stored in, or obtained from, the profile database 308. The profile database 308 stores information about financial institutions and checking accounts of the users of the system. The profile database 308 may also contain information regarding the user's identity (e.g., a template of the user's signature, driver license data, etc.).

The financial settlement engine 306 processes the dynamic check. In exemplary embodiments, the financial settlement engine 306 settles the funds or “clears” the check based on a routing number of the checking account. The process of settling may comprise providing information to both a payer's bank and the payee's bank related to the particular transaction involving the dynamic check.

The transaction repository 310 stores payment transaction information associated with the data processing center 108 over a period of time. Thus, the transaction repository 310 maintains a history of transactions, which may be later referenced to facilitate non-repudiation of a transaction.

The negative database 312 stores information related to high risk accounts or accounts having fraudulent activity associated therewith. For example, if a user has written several bad checks, that user's account may be listed with the negative database 312. Based on information stored in the negative database 312, the dynamic check may be declined (i.e., data processing center 108 declines to process the payment.)

It should be noted that the components of the data processing center 108 are logical services which may be implemented in hardware, software, firmware, or communication framework deployed in one or more data processing centers 108. In embodiments where more than one data processing centers 108 are provided, the data processing centers 108 may be designated to process data by physical location (e.g., location of the business entity 102 or financial institution 110) or by financial institutions 110 (e.g., payments for checking accounts at Citibank may be processed by one data processing center 108, while payments for checking accounts at Bank of America are processed by a different data processing center). Alternatively, the data processing centers 108 may be designated to process a certain type of information. For example, one data center may process data related to authentication, while a different processing center 108 may process data related to financial settlement.

FIG. 4 illustrates an example of a dynamic check 400. The dynamic check 400 is a digital representation of a traditional paper-based check that can be routed to a bank for processing in a completely paperless manner. According to one embodiment of the present invention, the dynamic check 400 is rendered in a graphical style similar to a style of the paper check normally issued to the user by his/her bank.

In one embodiment, the dynamic check 400 is implemented by defining an appropriate electronic document in an Extensible Markup Language (XML) format. Alternative embodiments may utilize other methods and language to implement the dynamic check 400.

In exemplary embodiments, the dynamic check 400 is generated by the POS terminal 104 by the processor 204 and displayed on the display device 206 (FIG. 2). In some embodiments, the POS terminal 104 retrieves the information necessary to generate the dynamic check 400 from the profile database 308 (FIG. 3) once the user is properly identified. The information may then be used by the POS terminal 104 to automatically fill in fields on the dynamic check 400. The information may include the user's name and address 402, bank name 404, bank routing number 406, and customer's checking account number 408.

In one embodiment, the user's check number 410 may also be obtained from the profile database 308 or be obtained in real time from the financial institution 110 (FIG. 1) and filled in on the dynamic check 400. The user may have the ability to change the check number 410 to match a next entry in cases where the user has already used the check number, but a check associated with the used check number has not been processed by the financial institution 110. In alternative embodiments, the check number 410 field may be left blank, and the user may enter it via, for example, the pressure sensitive pad 212 or the keypad 216 (FIG. 2).

A payment amount 412 may be automatically provided by the POS terminal 104. In exemplary embodiments, the POS terminal 104 is coupled to a cash register or other device which calculates a total payment amount due. This total payment amount may then be communicated to the POST terminal 104 via the communication interface 202, and the proper payment amount 412 provided on the dynamic check 400. In alternative embodiments, the payment amount 412 may entered by the user via, for example, the pressure sensitive pad 210 or the keypad 216.

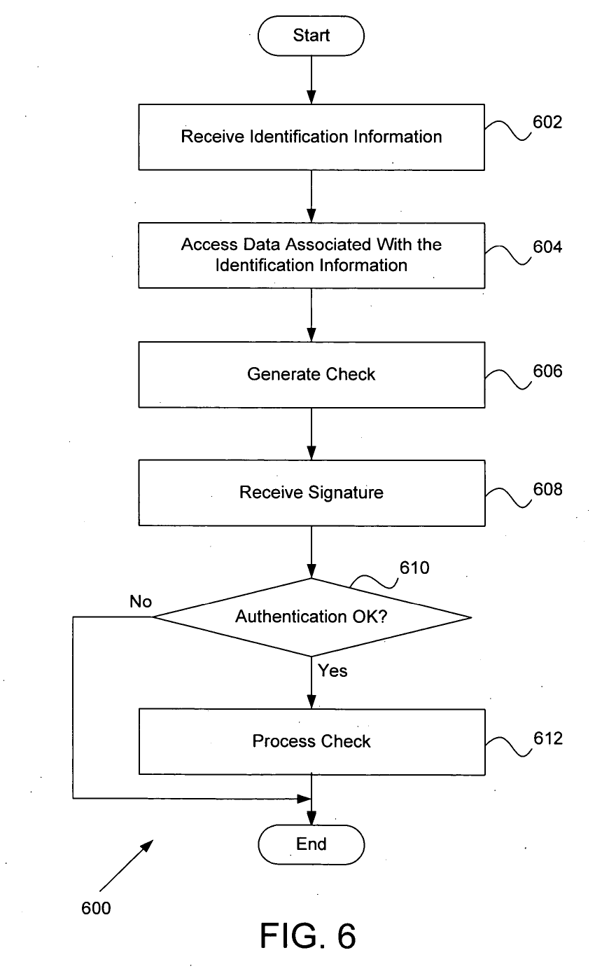

The dynamic check 400 further provides a signature field 414. The user authorizes payment by providing his/her signature in the signature field 414. The signature is then used by the POS terminal 104 to authenticate the user and authorize payment as will be discussed in more detail in connection with FIG. 6. Further, other forms of user verification/authentication may be used instead of, or in addition to, the signature, such as verification using a driver license.

Once the user verifies the information on the dynamic check 400 and provides a signature in the signature field 414, the user may select an enter button 416 to initiate checking processing as described in FIG. 6 below. Alternatively, if there is an error in on the dynamic check 400 or a mistake on the signature filed 414, the user may select a clear button 418.

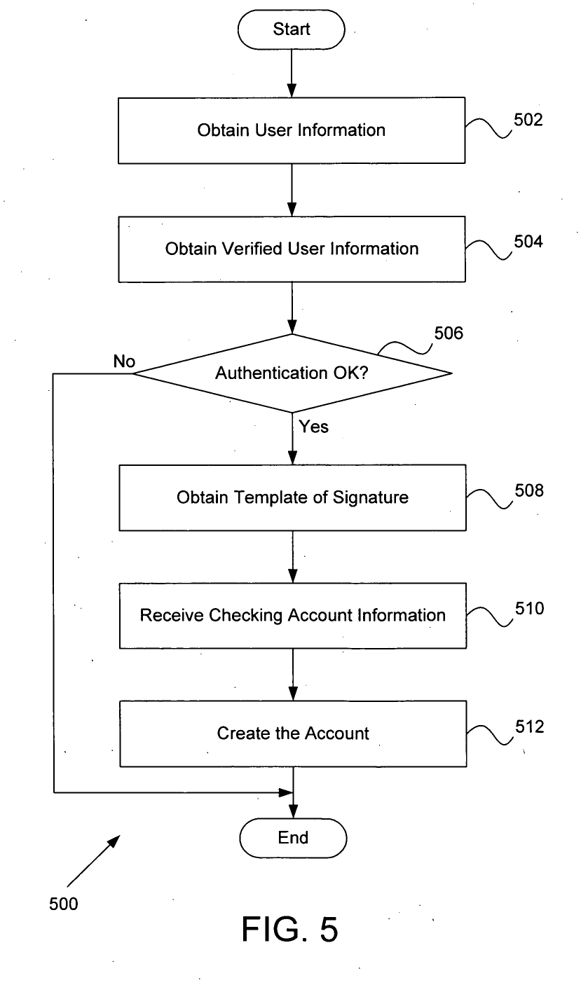

Referring now to FIG. 5, a flowchart 500 of an exemplary method for a new user to register with the data processing center 108 (FIG. 3) is shown. In order to establish a new account, the new user provides user information in step 502. The user information may be provided via the data input devices 208 (FIG. 2) and forwarded to the data processing center 108. The user information may comprise personal information such as name, address, telephone number, or any other personal information which may be unique to the user. In some embodiments, the user information may be obtained by swiping the user's driver license through the card reader 212 (FIG. 2), for example.

Next in step 504, verified information is obtained by the data processing center 104 for comparison to the new user information. In one embodiment, the user swipes his/her driver's license through the card reader. The information associated with the driver's license is then sent to the POS terminal 104. In an alternative embodiment, a clerk may manually review the new user's driver's license and enter the verified information (e.g., by swiping the card through a card reader).

In a further embodiment, the new user may be required to swipe one or more credit cards or ATM cards through the card reader. The data processing center then matches the credit card or ATM information to the information encoded on the driver's license.

In step 506, the user information received in step 502 is compared to the verified information obtained in step 506. Authentication may be performed by matching credit card information to the information encoded on, or provided by, the driver's license. Further, the information from the credit card and/or the driver's license may be compared to the user information. In an alternative embodiment, a clerk may manually verify the user information by reviewing the driver's license and indicating to the data processing center 108 that the user's information is verified.

Authentication may also comprise verifying that the user is not listed in the negative database 312 (FIG. 3). For example, the negative database 312 is checked to insure that the credit cards and/or driver's license are not recorded as stolen or lost. If the user is not authenticated because the information does not match or the user, credit card, and/or driver's license information is included in the negative database 312, then the registration process ends.

If, however, the user is authenticated, then a template of the user's signature is obtained in step 508. In one embodiment, the user is required to create a biometric template of his handwritten signature by signing one or more times on the pressure sensitive pad 210.

In step 510, the new user provides checking account information to be associated with his/her account. Accordingly, the user may scan a copy of a paper check via the check scanner 214 (FIG. 2). By scanning the paper check, information such as the bank routing number and checking account number may be obtained. Alternatively, the user may manually enter his/her routing and account numbers via the pressure sensitive pad 210 or the keypad 216. If the user has more than one checking account that he/she would like to associate with his/her account, the user may enter multiple account information in step 510.

Once the checking account information is received, the account is created in step 512. The associated account information is stored, according to one embodiment, in the profile database 308. The associated account information comprises at least the user personal information and checking account information along with the associated biometric signature template.

It should be noted that the method of FIG. 5 is exemplary. Alterative embodiments may comprise more, less, or functionally equivalent steps, and may practice the steps in a different order. For example, authentication (step 506) may occur after receiving the checking account information (step 510). In another alternative example, checking account information may be used as a part of the user information (step 502) or verified information (step 504). As a further example, steps 502 and 504 may be combined into a single step if the user information is obtained from a verified source such as a driver license.

Referring now to FIG. 6, a flowchart 600 of an exemplary method for processing a dynamic (electronic) check transaction is shown. When the registered user wants to transact an electronic payment utilizing a dynamic check, the user first provides user identification information. The identification information is received, in step 602, by the POS terminal 104 (FIG. 1). In one embodiment, the user may provide a unique piece of information such as a driver's license number, telephone number, or account user name via the pressure sensitive pad 210 or the keypad 216. Alternatively, the user may swipe his/her driver's license or an associated credit card via the card reader 212 (FIG. 2) in order to provide the identification information. In yet a further embodiment, the user may scan a paper check via the check scanner 214.

Once the identification information is received, data associated with the identification information is accessed in step 604. In one embodiment, the associated data is retrieved from the profile database 308 (FIG. 3).

Based on the associated data, a dynamic check is generated on the display device 206 (FIG. 2) in step 606. In exemplary embodiments, the user name and address 402, bank name 404, bank routing number 406, and customer's checking account number 408 (FIG. 4) are provided on the dynamic check. In some embodiments, the total payment amount due is also provided on the dynamic check.

If the user has more than one checking account associated with their account, the user may select the particular checking account from which payment should be made. In one embodiment, the user may select the particular checking account via the pressure sensitive pad 210 or the keypad 216.

The user may then review and verify the information on the dynamic check is correct. If some data is not correct, the user is able to correct the information via the pressure sensitive pad 210, keypad 216, or any other data input devices 208. If everything is correct, the user signs the dynamic check in order to create an authorized dynamic check, and the signature is sent to the authentication engine 304 (FIG. 3) in step 608 for comparison with the associated biometric signature template stored for the user. The authenticity of the signature may be verified using any number of biometric algorithms known in the art. In another embodiment, a set of structure data represented by the dynamic check 400 is digitally signed by cryptographically binding to the electronic representation of the handwritten signature using an algorithm known in the art. Such a process of digitally signing the dynamic check provides a mechanism to enforce non-repudiation of the payment transactions.

If the authentication engine 304 matches the signatures with the biometric signature template in step 610, then the authorized dynamic check (information) is sent to the financial settlement engine 306 (FIG. 3) for processing in step 612. If the signature does not match the biometric signature template in step 610, the dynamic check is denied, and the process ends.

If biometric signature verification is not available or in addition to, or instead of, biometric signature verification, the data processing center 108 may utilize a plurality of sources of identification information, including driver licenses or other forms of government-issued IDs and one or more credit cards. The authentication engine 304 may then validate the user via the corresponding identification source (e.g., credit card or driver license information) or consult one or more “negative lists” on the negative database 312.

While the embodiment of FIG. 6 authenticates the dynamic check at the data processing center 108, alternative embodiments may authenticate the dynamic check at the POS terminal 104, or at both locations. In some alternative embodiments, the data associated with the identification information (step 604) is obtained from the data processing center 108 and compared to the identification information (step 602) by the processor 204 (FIG. 2) at the POS terminal 104.

Once the dynamic check is sent to the financial settlement engine 306, the customer is presented with a receipt that may comprise a hardcopy of he dynamic check with his/her signature.

In a further embodiment, security of the payment transaction may be enhanced by analyzing previous patterns of use stored in the transaction repository 310 (FIG. 3) and the profile database 308. Suspicious transaction may be rejected by the system.

It should be noted that the method of FIG. 6 is exemplary. Alternative embodiments may comprise more, less, or functionally equivalent steps and still be within the scope of exemplary embodiments.

The present invention has been described above with reference to exemplary embodiments. It will be apparent to those skilled in the art that various modifications may be made and other embodiments can be used without departing from the broader scope of the present invention. Therefore, those and other variations upon the exemplary embodiments are intended to be covered by the present invention.

What is claimed is:

1. A system for utilizing dynamic checks, comprising:
a profile database configured to store user information and provide the user information for authentication and generation of the dynamic check;
an authentication engine coupled to the profile database and configured to verify an identity of a user and to verify a signature on the dynamic check by comparing the signature with a stored signature template; and
a financial settlement engine configured to settle the dynamic check.

2. The system of claim 1 wherein the profile database stores the stored signature template.

3. The system of claim 1 further comprising a transaction repository configured to store copies of transactions processed by the authentication engine.

4. The system of claim 1 further comprising a negative database configured to store information related to high risk accounts or accounts having fraudulent activity associated therewith.

5. The system of claim 1 further comprising a POS terminal configured to generate a representation of the dynamic check and receive user inputs associated with the dynamic check.

6. The system of claim 5 wherein the POS terminal comprises one or more data input devices configured to receive the user inputs including the signature.

7. The system of claim 5 wherein the POS terminal comprises a display device configured to display a graphical representation of the dynamic check.

8. A method for utilizing a dynamic check, comprising:
receiving user identification information;
generating a representation of the dynamic check, the representation of the dynamic check comprising user name and account information obtained based on the user identification information;
receiving a signature from a user, the signature presented via a field on the representation of the dynamic check; and
authenticating the dynamic check.

9. The method of claim 8 further comprising settling the dynamic check if the dynamic check is authenticated.

10. The method of claim 8 further comprising creating an account for the user by storing verified user information, a template of the signature from the user, and checking account information.

11. The method of claim 8 wherein receiving user identification information comprises obtaining information from a swiped driver's license or an associated credit card via a card reader.

12. The method of claim 8 wherein receiving user identification information comprises receiving a unique piece of information such as a driver's license number, telephone number, or account user name.

13. The method of claim 8 wherein generating the representation of the dynamic check comprises automatically providing a payment amount on the dynamic check.

14. The method of claim 8 further comprising receiving user edits to the dynamic check.

15. The method of claim 8 wherein authenticating the dynamic check comprises verifying the signature by comparing the signature with a stored template of the signature from the user.

16. The method of claim 8 wherein authenticating the dynamic check comprises referencing a negative database to determine if the user or account is high risk.

17. The method of claim 8 wherein authenticating the dynamic check comprises comparing a plurality of identification information sources to the user identification information.

18. The method of claim 17 wherein the plurality of identification information sources comprises a driver license, other forms of government-issued identification, or one or more credit cards.

19. An electronic readable medium having embodied thereon a program, the program being executable by a machine to perform a method for utilizing dynamic checks, the method comprising:
receiving user identification information;
generating a representation of the dynamic check, the representation of the dynamic check comprising user name and account information obtained based on the user identification information; and
receiving a signature from a user, the signature presented via a field on the representation of the dynamic check; and
authenticating an authorized dynamic check.
